(19) United States
(12) Patent Application Publication
(10) Pub. No.: US 2021/0005574 A1
(43) Pub. Date: Jan. 7, 2021

(54) SEMICONDUCTOR PACKAGE AND MANUFACTURING METHOD THEREOF

(71) Applicant: ORIENT SEMICONDUCTOR ELECTRONICS, LIMITED, KAOHSIUNG (TW)

(72) Inventors: YUEH-MING TUNG, KAOHSIUNG (TW); CHIA-MING YANG, KAOHSIUNG (TW); HUI-YEN TSAI, KAOHSIUNG (TW); YU-CHEN LIN, KAOHSIUNG (TW); PEI-JUNG SU, KAOHSIUNG (TW)

(21) Appl. No.: 16/815,398

(22) Filed: Mar. 11, 2020

(30) Foreign Application Priority Data
Jul. 2, 2019 (TW) 108123337

(51) Int. Cl. H01L 25/065; H01L 25/00; G06K 19/077

(52) U.S. Cl. CPC H01L 25/0652; H01L 25/50; G06K 19/0772; H01L 2225/06582; H01L 2225/0652; H01L 2225/06555; H01L 2225/0651

(57) ABSTRACT

The present disclosure provides a semiconductor package. The semiconductor package includes a first substrate, a first die, a plurality of first electrical contacts, a first encapsulant, a second substrate, a second die, a third die, a plurality of second electrical contacts, a second encapsulant and an adhesive layer. The first die is disposed on a first surface of the first substrate. The first electrical contacts are disposed on a second surface of the first substrate and are electrically connected to the first die. The first encapsulant is formed on the first surface of the first substrate to enclose the first die. The second and third dies are disposed on a first surface of the second substrate. The second electrical contacts are disposed on a second surface of the second substrate and are electrically connected to the second and third dies. The second encapsulant is formed on the first surface of the second substrate to enclose the second and third dies. The adhesive layer is disposed between the first and second encapsulants to attach the first encapsulant to the second encapsulant. The present disclosure further provides a method of manufacturing the above semiconductor package.

### RELATED APPLICATION

The present application is based on and claims priority to Taiwanese Application Number 108123337, filed Jul. 2, 2019, the disclosure of which is hereby incorporated by reference herein in its entirety.

### BACKGROUND

### 1. Technical Field

This disclosure relates to a semiconductor package and a manufacturing method thereof, and more particularly relates to a semiconductor package having a memory card and a SIM card, and a manufacturing method thereof.

### 2. Description of the Related Art

Many existing mobile phones are designed to allow users to increase data storage capacity themselves by inserting a memory card. To achieve the above design, the phones each usually have a slot to receive separate memory and SIM cards which are carried by a tray. However, it is a little inconvenient for users to carry two separate cards on their mobile phones.

### SUMMARY

In view of the above, the present disclosure provides a semiconductor package and a manufacturing method thereof that are convenient for users to use both memory and SIM cards.

In the first embodiment, the semiconductor package of the present disclosure includes a first substrate, a second substrate, a first die, a second die, a third die, a plurality of first electrical contacts, a plurality of second electrical contacts, a first encapsulant, a second encapsulant and an adhesive layer. The first and second substrates each have opposing first surface and second surface. The first die is disposed on the first surface of the first substrate. The second die and the third die are disposed on the first surface of the second substrate. The first electrical contacts are disposed on the second surface of the first substrate and electrically connected to the first die. The first electrical contacts are to be electrically connected to a first external circuit. The second electrical contacts are disposed on the second surface of the second substrate and electrically connected to the second die and the third die respectively. The second electrical contacts are to be electrically connected to a second external circuit. The first encapsulant is formed on the first surface of the first substrate to enclose the first die, wherein the first encapsulant has a bottom surface. The second encapsulant is formed on the first surface of the second substrate to enclose the second die and the third die, wherein the second encapsulant has a top surface. The adhesive layer is formed between the first encapsulant and the second encapsulant, and adhered to the bottom surface of the first encapsulant and the top surface of the second encapsulant.

In the second embodiment, the semiconductor package of the present disclosure includes a first substrate, a second substrate, a first die, a second die, a third die, a plurality of first electrical contacts, a plurality of second electrical contacts, a plurality of support members and an encapsulant. The first and second substrates each have opposing first surface and second surface. The first die is disposed on the first surface of the first substrate. The second die and the third die are disposed on the first surface of the second substrate. The first electrical contacts are disposed on the second surface of the first substrate and electrically connected to the first die. The first electrical contacts are to be electrically connected to a first external circuit. The second electrical contacts are disposed on the second surface of the second substrate and electrically connected to the second die and the third die respectively. The second electrical contacts are to be electrically connected to a second external circuit. The support members are disposed between the first substrate and the second substrate to maintain a distance between the first substrate and the second substrate. The encapsulant is formed between the first substrate and the second substrate to enclose the first die, the second die, the third die and the support members.

The method of manufacturing a semiconductor package comprises: providing a first substrate having opposing first surface and second surface, wherein a plurality of first electrical contacts is disposed on the second surface of the first substrate, the first electrical contacts being configured to be electrically connected to a first external circuit; disposing a first die on the first surface of the first substrate and electrically connecting the first die to the first electrical contacts; forming a plurality of solder balls on the first surface of the first substrate; providing a second substrate having opposing first surface and second surface, wherein a plurality of second electrical contacts is disposed on the second surface of the second substrate, the second electrical contacts being configured to be electrically connected to a second external circuit; disposing a second die and a third die on the first surface of the second substrate and electrically connecting the second die and the third die to the second electrical contacts respectively; melting and then cooling the solder balls to form a plurality of support members for maintaining a distance between the first substrate and the second substrate; and forming an encapsulant between the first substrate and the second substrate to enclose the first die, the second die, the third die and the support members.

According to the semiconductor package of the present disclosure, a memory card and a SIM card are integrated together in a package. A user may flip the package as required and insert it into a slot of a mobile phone such that the gold fingers on the upper or lower surface of the package contact the gold fingers in the phone respectively to change the use of the SIM card or memory card.

The foregoing, as well as additional objects, features and advantages of the disclosure will be more readily apparent from the following detailed description, which proceeds with reference to the accompanying drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the semiconductor package according to the first embodiment of the present disclosure.

FIG. 2 is a schematic diagram of the semiconductor package according to the second embodiment of the present disclosure.

FIGS. 3 to 7 illustrate the method of manufacturing the semiconductor package of FIG. 2.

### DETAILED DESCRIPTION OF THE PREFERRED EMBODIMENT

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

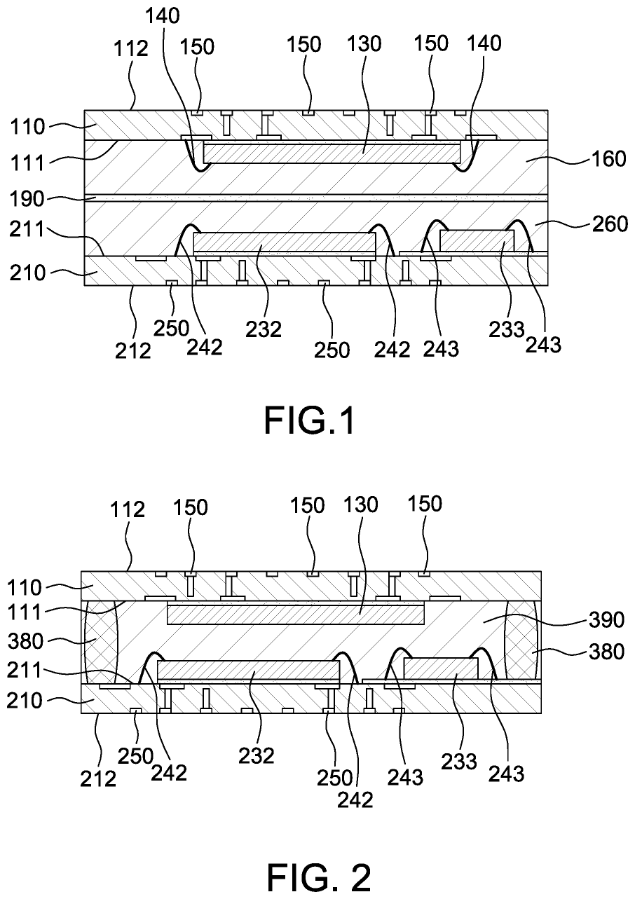

Referring to FIG. 1, the semiconductor package according to the first embodiment of the present disclosure includes a first substrate 110. The first substrate 110 may be a single-layer or multi-layer circuit board, but is not limited thereto. The first substrate 110 has opposing first surface 111 and second surface 112, and the first surface 111 and the second surface 112 are located on different planes. For example, the first surface 111 is a bottom surface and the second surface 112 is a top surface, but is not limited thereto. The first surface 111 is provided with a first die 130 thereon and the first die 130 may be a subscriber identity module (SIM) die, but is not limited thereto. The first die 130 has opposing first surface and second surface. The first surface of the first die 130 is attached to the first surface 111 of the first substrate 110 through an adhesive layer. The second surface of the first die 130 is an active surface. The first substrate 110 is further provided with a plurality of first bonding wires 140. One end of each of the first bonding wires 140 is connected to the active surface of the first die 130 and the other end is connected to the first surface 111 of the first substrate 110. Therefore, the first die 130 is electrically connected to the first substrate 110 through the first bonding wires 140. In addition to the above embodiment, the first die 130 may also be disposed on the first surface 111 of the first substrate 110 in a flip-chip manner. More specifically, a plurality of solder balls is provided on the active surface of the first die 130. The active surface of the first die 130 is positioned to face the first surface 111 of the first substrate 110. The solder balls are then melted by a reflow process to electrically connect the active surface of the first die 130 to the first substrate 110. Since the flip-chip technology is conventional, it will not be further explained.

The first surface 111 of the first substrate 110 is further provided with a first encapsulant 160. The first encapsulant 160 encloses the first die 130 and the first bonding wires 140. The first encapsulant 160 has a flat bottom surface, but is not limited thereto. The first encapsulant 160 may also have a rugged bottom surface. The second surface 112 of the first substrate 110 is provided with a plurality of first electrical contacts 150, and the first electrical contacts 150 may be gold fingers. The first electrical contacts 150 are electrically connected to the first die 130 by the traces on the first substrate 110 and the first bonding wires 140. The first die 130 may be electrically connected to an external circuit through the first electrical contacts 150 on the first substrate 110.

The semiconductor package according to the first embodiment of the present disclosure further includes a second substrate 210. The second substrate 210 may be a single-layer or multi-layer circuit board, but is not limited thereto. The second substrate 210 has opposing first surface 211 and second surface 212, and the first surface 211 and the second surface 212 are located on different planes. For example, the first surface 211 is a top surface and the second surface 212 is a bottom surface, but is not limited thereto. The first surface 211 is provided with a plurality of dies including a second die 232 and a third die 233. The second die 232 may be a non-volatile memory die, such as a flash memory die, but is not limited thereto. The third die 233 may be a controller die, but is not limited thereto. The second die 232 and the third die 233 each have opposing first surface and second surface. The first surface of the second die 232 is attached to the first surface 211 of the second substrate 210 through an adhesive layer. The second surface of the second die 232 is an active surface. The first surface of the third die 233 is attached to the first surface 211 of the second substrate 210 through an adhesive layer. The second surface of the third die 233 is an active surface. The second substrate 210 is further provided with a plurality of second bonding wires 242 and a plurality of third bonding wires 243. One end of each of the second bonding wires 242 is connected to the active surface of the second die 232 and the other end is connected to the first surface 211 of the second substrate 210. One end of each of the third bonding wires 243 is connected to the active surface of the third die 233 and the other end is connected to the first surface 211 of the second substrate 210. Therefore, the second die 232 is electrically connected to the second substrate 210 through the second bonding wires 242 and the third die 233 is electrically connected to the second substrate 210 through the third bonding wires 243. In addition to the above embodiment, the second die 232 and/or third die 233 may also be disposed on the first surface 211 of the second substrate 210 in a flip-chip manner.

The first surface 211 of the second substrate 210 is further provided with a second encapsulant 260. The second encapsulant 260 encloses the second die 232, third die 233, second bonding wires 242 and third bonding wires 243. The second encapsulant 260 has a flat top surface, but is not limited thereto. The second encapsulant 260 may also have a rugged top surface. The second surface 212 of the second substrate 210 is provided with a plurality of second electrical contacts 250, and the second electrical contacts 250 may be gold fingers. The second electrical contacts 250 are electrically connected to the second die 232 by the traces on the second substrate 210 and the second bonding wires 242. The second electrical contacts 250 are electrically connected to the third die 233 by the traces on the second substrate 210 and the third bonding wires 243. The second die 232 and the third die 233 may be electrically connected to an external circuit through the second electrical contacts 250 on the second substrate 210. The first encapsulant 160 is fixed above the second encapsulant 260. Further, an adhesive layer 190 is disposed between the first encapsulant 160 and the second encapsulant 260. The adhesive layer 190 is adhered to the bottom surface of the first encapsulant 160 and the top surface of the second encapsulant 260. That is, the bottom surface of the first encapsulant 160 is bonded to the top surface of the second encapsulant 260 through the adhesive layer 190.

The semiconductor package according to the first embodiment of the present disclosure actually includes a first package and a second package that may operate independently, wherein the first package is fixed above the second package. The first package includes the first substrate 110, the first die 130, the first bonding wires 140, and the first electrical contacts 150. The second package includes the second substrate 210, the second die 232, the third die 233, the second bonding wires 242, the third bonding wires 243, and the second electrical contacts 250.

Referring to FIG. 2, the semiconductor package according to the second embodiment of the present disclosure also includes the first substrate 110, the second substrate 210, the first die 130, the second die 232, the third die 233, the second bonding wires 242, and the third bonding wires 243 in the semiconductor package according to the first embodiment of the present disclosure. In these figures identical reference numerals have been used when designating substantially identical elements that are common to the figures. In comparison with the first embodiment, the first die 130 in this embodiment is disposed on the first surface 111 of the first substrate 110. The second die 232 and the third die 233 are disposed on the first surface 211 of the second substrate 210, and electrically connected to the second substrate 210 through the second bonding wires 242 and the third bonding wires 243 respectively. The first die 130 may be electrically connected to an external circuit through the first electrical contacts 150 on the second surface 112 of the first substrate 110. The second die 232 and the third die 233 may be electrically connected to an external circuit through the second electrical contacts 250 on the second surface 212 of the second substrate 210.

However, the first die 130 in this embodiment is disposed on the first substrate 110 in a flip-chip manner. A plurality of support members 380 is disposed between the first substrate 110 and the second substrate 210 to maintain a distance between the first substrate 110 and the second substrate 210. An encapsulant 390 is further provided between the first substrate 110 and the second substrate 210 to enclose the first die 130, the second die 232, the third die 233, the second bonding wires 242, the third bonding wires 243, and the support members 380. The support members 380 may be made of metal, such as tin, but is not limited thereto. The support members 380 may also be made of a non-metal material. When the support members 380 are made of metal, they may be used as conductive traces for electrically connecting the first substrate 110 and the second substrate 210. In addition to the above embodiments, the first die 130 may also be electrically connected to the first substrate 110 through a plurality of bonding wires, and the second die 232 and/or the third die 233 may also be disposed on the first surface 211 of the second substrate 210 in a flip-chip manner.

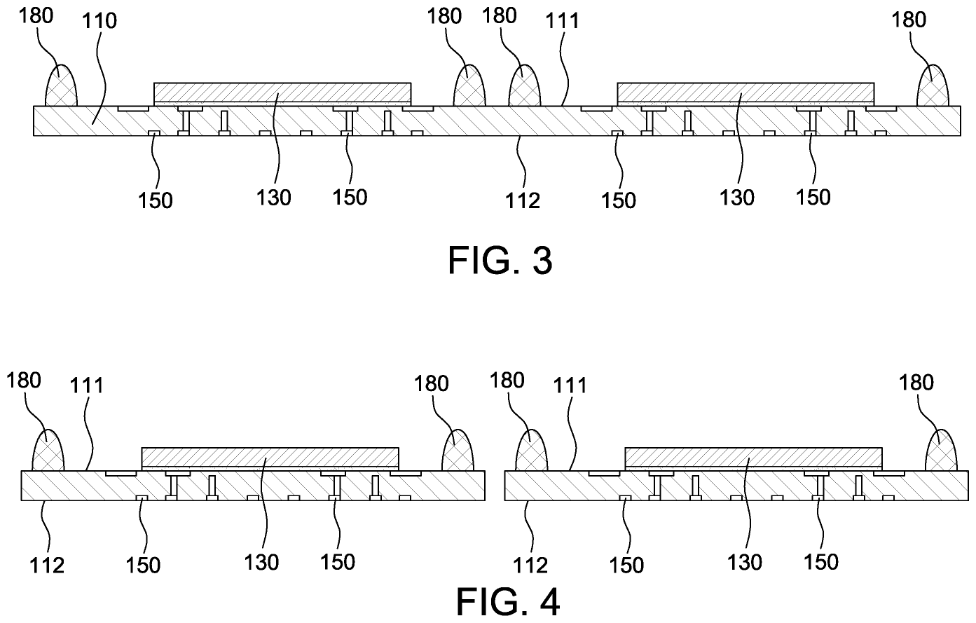

FIGS. 3 to 7 show a method of manufacturing the semiconductor package of FIG. 2. Referring to FIG. 3, a first substrate 110 is provided. The first substrate 110 has opposing first surface 111 and second surface 112. A plurality of first dies 130 is disposed on the first surface 111 of the first substrate 110 in a flip-chip manner, but is not limited thereto, so that the first dies 130 are electrically connected to the first substrate 110. A plurality of solder balls 180 is formed on the first surface 111 of the first substrate 110. A plurality of first electrical contacts 150 is formed on the second surface 112 of the first substrate 110. The first electrical contacts 150 may be electrically connected to the first dies 130, respectively.

Referring to FIG. 4, the first substrate 110 is then cut such that the divided parts of the first substrate 110 each is provided with one of the first dies 130, a plurality of the solder balls 180 and a plurality of the first electrical contacts 150.

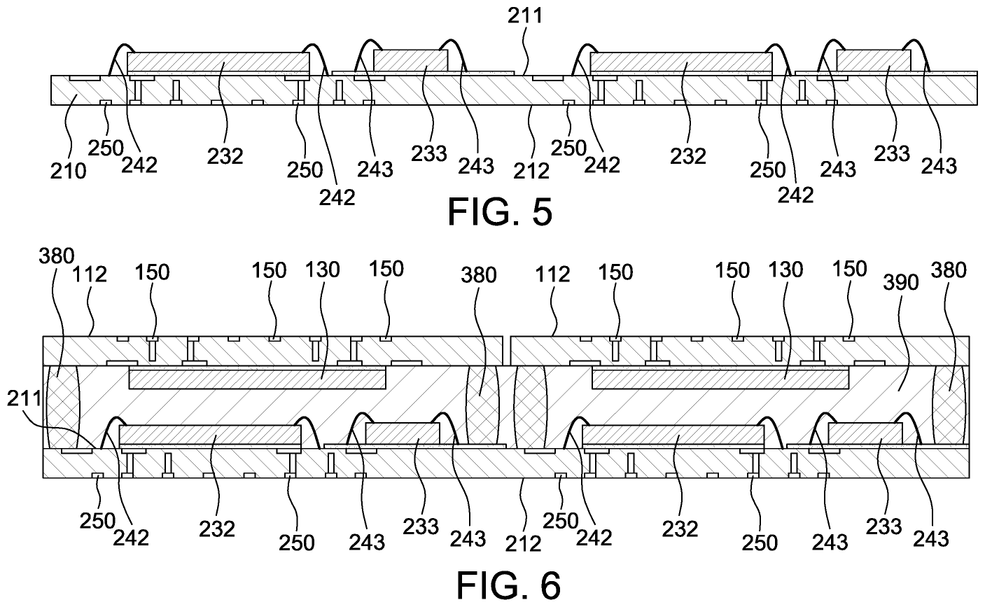

Referring to FIG. 5, a second substrate 210 is provided. The second substrate 210 has opposing first surface 211 and second surface 212. A plurality of second dies 232 and a plurality of third dies 233 are attached to the first surface 211 of the second substrate 210 respectively through an adhesive layer. A plurality of second bonding wires 242 and a plurality of third bonding wires 243 are provided on the second substrate 210 so that the second dies 232 and the third dies 233 are electrically connected to the second substrate 210 through the second bonding wires 242 and the third bonding wires 243 respectively. A plurality of second electrical contacts 250 are formed on the second surface 212 of the second substrate 210 so that the second dies 232 and the third dies 233 may be electrically connected to external circuits through the second electrical contacts 250 respectively.

Referring to FIG. 6, the solder balls 180 on the divided parts of the first substrate 110 are heated and melted through a reflow process to bond to the first surface 211 of the second substrate 210. After cooling, the solder balls 180 are formed into a plurality of support members 380 for maintaining a distance between the first substrate 110 and the second substrate 210. An encapsulant 390 is then formed between the first substrate 110 and the second substrate 210 to enclose the first dies 130, the second dies 232, the third dies 233, the second bonding wires 242, the third bonding wires 243, and the support members 380.

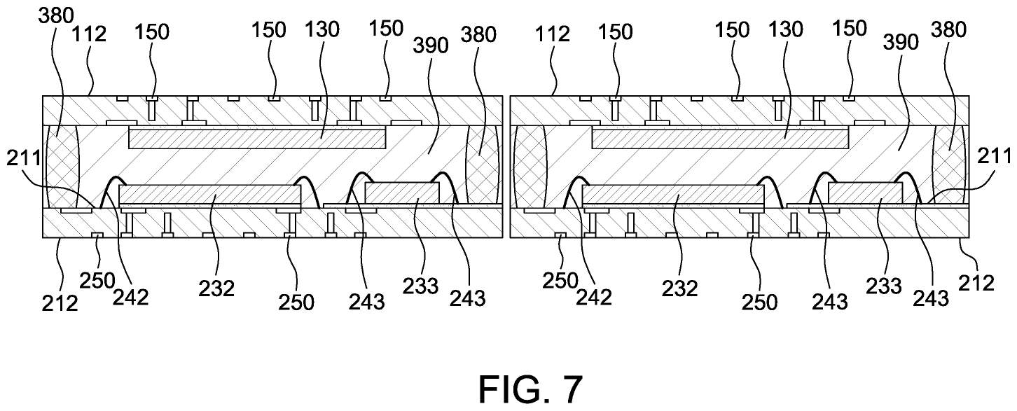

Referring to FIG. 7, the encapsulant 390 and the second substrate 210 are divided to form a plurality of semiconductor packages of FIG. 2.

According to the semiconductor package of the present disclosure, a memory card and a SIM card are integrated together in a package. A user may flip the package as required and insert it into a slot of a mobile phone such that the gold fingers on the upper or lower surface of the package contact the gold fingers in the phone respectively to change the use of the SIM card or memory card.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A semiconductor package, comprising:
a first substrate having opposing first surface and second surface;
a first die disposed on the first surface of the first substrate;
a plurality of first electrical contacts disposed on the second surface of the first substrate and electrically connected to the first die, the first electrical contacts being configured to be electrically connected to a first external circuit;
a first encapsulant formed on the first surface of the first substrate to enclose the first die, the first encapsulant having a bottom surface;
a second substrate having opposing first surface and second surface;
a second die and a third die both disposed on the first surface of the second substrate;
a plurality of second electrical contacts disposed on the second surface of the second substrate and electrically connected to the second die and the third die respectively, the second electrical contacts being configured to be electrically connected to a second external circuit;
a second encapsulant formed on the first surface of the second substrate to enclose the second die and the third die, the second encapsulant having a top surface; and
an adhesive layer formed between the first encapsulant and the second encapsulant, the adhesive layer being adhered to the bottom surface of the first encapsulant and the top surface of the second encapsulant.

2. The semiconductor package as claimed in claim 1, further comprising:
a plurality of first bonding wires enclosed by the first encapsulant, the first bonding wires electrically connecting the first die to the first substrate;
a plurality of second bonding wires enclosed by the second encapsulant, the second bonding wires electrically connecting the second die to the second substrate; and
a plurality of third bonding wires enclosed by the second encapsulant, the third bonding wires electrically connecting the third die to the second substrate.

3. The semiconductor package as claimed in claim 1, wherein the first die is a subscriber identity module (SIM) die, the second die being a non-volatile memory die, and the third die being a controller die.

4. A semiconductor package, comprising:
a first substrate having opposing first surface and second surface;
a first die disposed on the first surface of the first substrate;
a plurality of first electrical contacts disposed on the second surface of the first substrate and electrically connected to the first die, the first electrical contacts being configured to be electrically connected to a first external circuit;
a second substrate having opposing first surface and second surface;
a second die and a third die both disposed on the first surface of the second substrate;
a plurality of second electrical contacts disposed on the second surface of the second substrate and electrically connected to the second die and the third die respectively, the second electrical contacts being configured to be electrically connected to a second external circuit;
a plurality of support members disposed between the first substrate and the second substrate to maintain a distance between the first substrate and the second substrate; and
an encapsulant formed between the first substrate and the second substrate to enclose the first die, the second die, the third die and the support members.

5. The semiconductor package as claimed in claim 4, further comprising:
a plurality of second bonding wires enclosed by the encapsulant, the second bonding wires electrically connecting the second die to the second substrate; and
a plurality of third bonding wires enclosed by the encapsulant, the third bonding wires electrically connecting the third die to the second substrate.

6. The semiconductor package as claimed in claim 4, wherein the first die is a subscriber identity module (SIM) die, the second die being a non-volatile memory die, and the third die being a controller die.

7. The semiconductor package as claimed in claim 4, wherein the support members are made of tin.

8. A method of manufacturing a semiconductor package, comprising:
providing a first substrate having opposing first surface and second surface, wherein a plurality of first electrical contacts is disposed on the second surface of the first substrate, the first electrical contacts being configured to be electrically connected to a first external circuit;
disposing a first die on the first surface of the first substrate and electrically connecting the first die to the first electrical contacts;
forming a plurality of solder balls on the first surface of the first substrate;
providing a second substrate having opposing first surface and second surface, wherein a plurality of second electrical contacts is disposed on the second surface of the second substrate, the second electrical contacts being configured to be electrically connected to a second external circuit;
disposing a second die and a third die on the first surface of the second substrate and electrically connecting the second die and the third die to the second electrical contacts respectively;
melting and then cooling the solder balls to form a plurality of support members for maintaining a distance between the first substrate and the second substrate; and
forming an encapsulant between the first substrate and the second substrate to enclose the first die, the second die, the third die and the support members.

9. The method as claimed in claim 8, further comprising:
disposing a plurality of second bonding wires to electrically connect the second die to the second substrate, wherein the second bonding wires are enclosed by the encapsulant; and
disposing a plurality of third bonding wires to electrically connect the third die to the second substrate, wherein the third bonding wires are enclosed by the encapsulant.

10. The method as claimed in claim 8, wherein the first die is a subscriber identity module (SIM) die, the second die being a non-volatile memory die, and the third die being a controller die.
